(19) United States
(12) Patent Application Publication
(10) Pub. No.: US 2017/0148761 A1
(43) Pub. Date: May 25, 2017

(54) METHOD OF FABRICATING SEMICONDUCTOR PACKAGE

(71) Applicant: Siliconware Precision Industries Co., Ltd., Taichung (TW)

(72) Inventors: Guang-Hwa Ma, Taichung (TW); Shih-Kuang Chiu, Taichung (TW); Shih-Ching Chen, Taichung (TW); Chun-Chi Ke, Taichung (TW); Chang-Lun Lu, Taichung (TW); Chun-Hung Lu, Taichung (TW); Hsien-Wen Chen, Taichung (TW); Chun-Tang Lin, Taichung (TW); Yi-Che Lai, Taichung (TW); Chi-Hsin Chiu, Taichung (TW); Wen-Tsung Tseng, Taichung (TW); Tsung-Te Yuan, Taichung (TW); Lu-Yi Chen, Taichung (TW); Mao-Hua Yeh, Taichung (TW)

(21) Appl. No.: 15/400,608

(22) Filed: Jan. 6, 2017

Related U.S. Application Data
(62) Division of application No. 14/012,447, filed on Aug. 28, 2013.

(30) Foreign Application Priority Data
Aug. 2, 2013 (TW) 102127732

(51) Int. Cl. H01L 23/00; H01L 21/683; H01L 23/538; H01L 21/56

(52) U.S. Cl. CPC H01L 24/96; H01L 21/568; H01L 21/6835; H01L 23/5389; H01L 2221/68359; H01L 2221/68372; H01L 2221/68377

(57) ABSTRACT

The present invention provides a semiconductor package and a method of fabricating the same, including: placing in a groove of a carrier a semiconductor element having opposing active and non-active surfaces, and side surfaces abutting the active surface and the non-active surface; applying an adhesive material in the groove and around a periphery of the side surfaces of the semiconductor element; forming a dielectric layer on the adhesive material and the active surface of the semiconductor element; forming on the dielectric layer a circuit layer electrically connected to the semiconductor element; and removing a first portion of the carrier below the groove to keep a second portion of the carrier on a side wall of the groove intact for the second portion to function as a supporting member. The present invention does not require formation of a silicon interposer, and therefore the overall cost of a final product is much reduced.

### BACKGROUND OF THE INVENTION

1. Field of the Invention

The present invention relates to semiconductor packages and a method of fabricating the same, and, more particularly, to a semiconductor package having wafer level circuits and a method of fabricating the same.

2. Description of the Prior Art

As the technology for developing electronic products is steadily growing, electronic products have now moved to multi-functionality and high functionality. The semiconductor packaging technology has been widely used nowadays to chip scale package (CSP), Direct Chip Attached (DCA), Multi Chip Module (MCM), and 3D-IC stacking technology.

FIG. 1 is a schematic cross-sectional view of a conventional semiconductor package, wherein a through silicon interposer (TSI) 10 is formed between a substrate 18 and a semiconductor chip 11. The TSI 10 has through-silicon vias (TSV) 100 and a redistribution layer (RDL) 15 formed on the through-silicon via (TSV) 100, allowing the redistribution layer 15 through each of the plurality of conductive elements 17 to be electrically connected with solder pads 180 on the substrate 18. The spacing distance between any two of the solder pads 180 is greater than that of the conductive elements 17. The conductive elements 17 are covered by an adhesive material, and the electrode pads 110 of the semiconductor chip 11 are electrically connected to the through-silicon via (TSV) 100 through a plurality of solder bumps 19. An adhesive material is then applied to cover the solder bumps 19.

If the semiconductor chip 11 is directly attached to the substrate 18, since the heat expansion coefficient difference between the smaller semiconductor chip and larger circuit substrate, it is difficult to establish a good bonding between the solder bumps 19 on the periphery of the chip 11 and the corresponding solder pads 180, causing the solder bumps 19 to be easily detached from the substrate 18. In addition, due to problems associated with thermal stress and warpage as a result of mismatch of heat expansion coefficient between semiconductor chip and substrate, the reliability between the semiconductor chip and the substrate is decreased causing frequent failures in reliability test.

Accordingly, by providing an interposer 10 made of silicon in the process of fabricating the semiconductor substrate, since the material thereof is similar to the semiconductor chip 11, the conventional problems can be solved.

The only concern in the foregoing fabricating method of the semiconductor package 1 is the fabrication cost of the through-silicon via (TSV) 100 in the silicon interposer 10, which includes forming the via and the metal underfill process. The total cost of the through-silicon via (TSV) 100 is 40-50% of the total cost in the fabricating process. Hence, it is difficult to lower the overall cost.

Moreover, the technical difficulty in fabricating the silicon interposer 10 is high, and hence below the same fabricating cost, the yield of the semiconductor package 1 is relatively low.

Therefore, there is an urgent need in solving the foregoing problems.

### SUMMARY OF THE INVENTION

In light of the foregoing drawbacks of the prior art, the present invention proposes a semiconductor package, comprising: a semiconductor element having opposing active and non-active surfaces and side surfaces abutting the active surface and the non-active surface; an adhesive material applied around a periphery of the side surfaces of the semiconductor element; a dielectric layer formed on the adhesive material and the active surface of the semiconductor element; and a circuit layer formed on the dielectric layer and electrically connected to the semiconductor element.

In an embodiment, the semiconductor package further comprises a supporting member surrounding the adhesive material. The supporting member can be a silicon-containing frame, and has a height greater than or not greater than a thickness of the semiconductor element.

The present invention further proposes a method of fabricating a semiconductor package, comprising: placing in a groove of a carrier a semiconductor element having opposing active and non-active surfaces and side surfaces abutting the active surface and the non-active surface; applying an adhesive material in the groove and around a periphery of the side surfaces of the semiconductor element; forming a dielectric layer on the adhesive material and the active surface of the semiconductor element; forming on the dielectric layer a circuit layer electrically connected to the semiconductor element; and removing a first portion of the carrier below the groove to keep a second portion of the carrier on a side wall of the groove intact for the second portion to function as a supporting member.

In an embodiment, the carrier is a silicon-containing board.

In an embodiment, the carrier has a plurality grooves, and, a singulation process is performed after the first portion of the carrier below the groove is removed, and the supporting member is also removed during the singulation process.

In an embodiment, the semiconductor element protrudes or does not protrude from the groove.

In an embodiment, through the non-active surface, the semiconductor element is adhered in the groove via an adhesive layer. The bonding layer is between 5 to 25 μm in thickness, and is removed at the same time when the first portion of the carrier below the groove is removed.

In an embodiment, the groove is filled with a dielectric layer covering the periphery of the side surfaces of the semiconductor element.

In an embodiment, the semiconductor element is a multi-chip module or a single-chip package.

In an embodiment, the semiconductor element is between 10 to 300 μm in thickness.

In an embodiment, the dielectric layer and the adhesive material are made of different materials, and the dielectric is made of an organic material or a non-organic material.

In an embodiment, the circuit layer has a plurality of conductive vias for being electrically connected with the semiconductor element.

The semiconductor package and the method of fabricating the same further comprise forming a redistribution layer on the dielectric layer and the circuit layer. The redistribution layer is electrically connected with the circuit layer. After the first portion of the carrier below the groove is removed, a substrate is attached to and electrically connected to the redistribution layer. In an embodiment, the redistribution layer comprises stacked dielectric portion and circuit portion and the dielectric portion is made of an organic material or a non-organic material.

The semiconductor package and the method of fabricating the same further comprise attaching and electrically connecting the substrate onto the circuit layer after the first portion of the carrier below the groove is removed.

The semiconductor package and the method of fabricating the same further comprise forming an etch-stop layer on the active surface of the semiconductor element before forming the dielectric layer, allowing the dielectric layer to be formed on the etch-stop layer. For example, before the etch-stop layer is formed, a dielectric material is formed on the adhesive material and the active surface of the semiconductor element, so as to cover the side surfaces of the semiconductor element. An opening is formed through the dielectric material to expose the active surface of the semiconductor element, allowing the etch-stop layer to be formed on the active surface of the semiconductor element. In an embodiment, the etch-stop layer is made of silicon nitride, and the dielectric material is made of an organic material or a non-organic material.

In an embodiment, the non-organic material is silicon oxide (SiO₂) or silicon nitride (SiₓN_{y}), and the organic material is Polyimide (PI), Polybenzoxazole (PBO), or Benzocyciclobutene (BCB).

Accordingly, in the semiconductor package and the method of fabricating the same, it is no longer required to have a conventional silicon interposer, as a result the overall fabricating cost is significantly reduced, and the fabricating process is simplified, ensuring the productivity and yield of the final semiconductor package to be significantly improved.

### BRIEF DESCRIPTION OF THE DRAWINGS

The present invention can be more fully understood by reading the following detailed description of the preferred embodiments, with reference made to the accompanying drawings, wherein:

FIG. 1 is a schematic cross-sectional view of a conventional semiconductor package;

FIGS. 2A-2H are schematic cross-sectional views of a semiconductor package in accordance with a first embodiment of the present invention, wherein FIGS. 2B′ and 2B″ represent other embodiments of FIG. 2B, FIGS. 2G′ and 2G″ represent other embodiments of FIG. 2G, and FIGS. 2H′ and 2H′″ represent other embodiments of FIG. 2H.

FIGS. 3A-3E are schematic cross-sectional views of a semiconductor package in accordance with a second embodiment of the present invention, wherein FIGS. 3C′ and 3C″ represent other embodiments of FIG. 3C, and FIGS. 3E′ and 3E″ represent other embodiments of FIG. 3E.

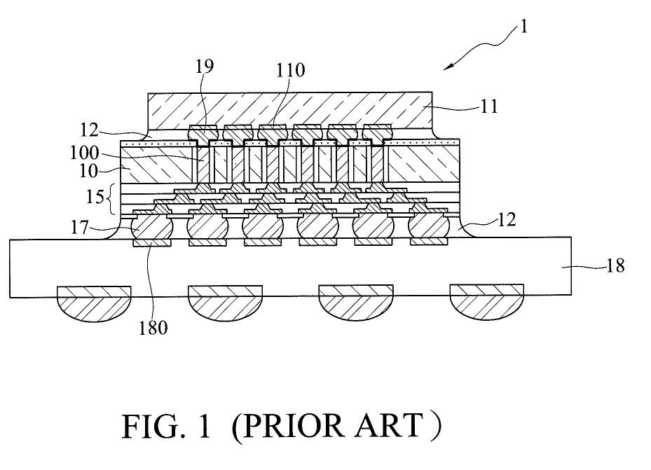

### DETAILED DESCRIPTION OF THE PREFERRED EMBODIMENTS

The present invention is described in the following with specific embodiments, so that one skilled in the pertinent art can easily understand other advantages and effects of the present invention from the disclosure of the present invention.

It is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements. In addition, words such as “on”, “top” and “a” are used to explain the preferred embodiment of the present invention only and should not limit the scope of the present invention.

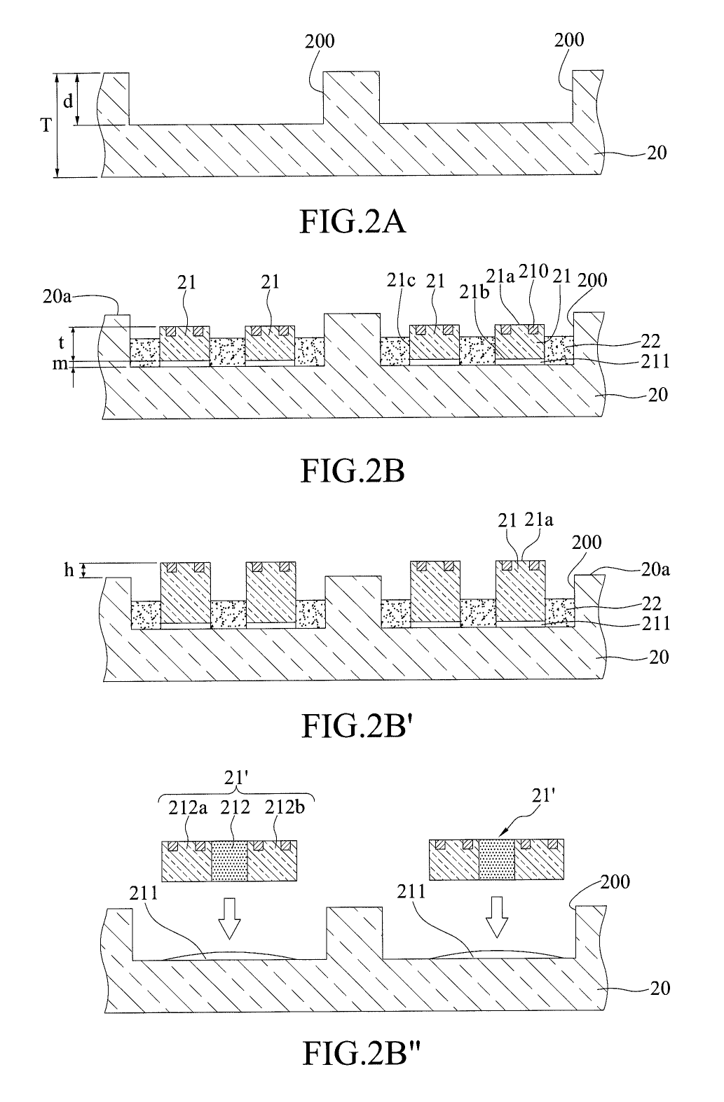

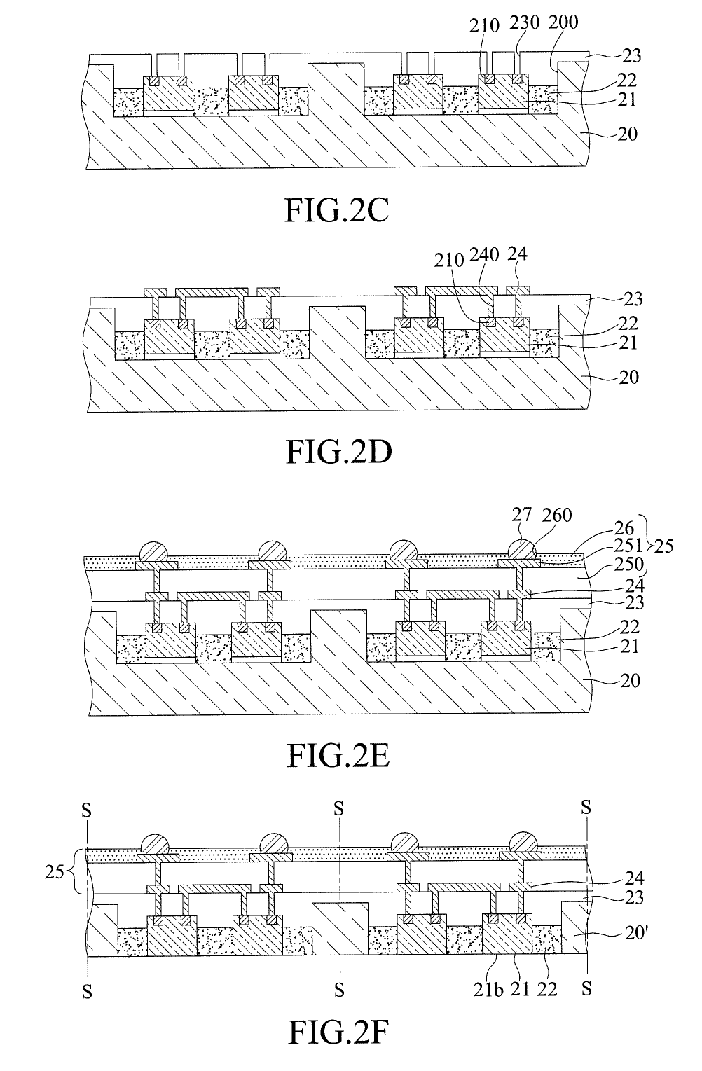

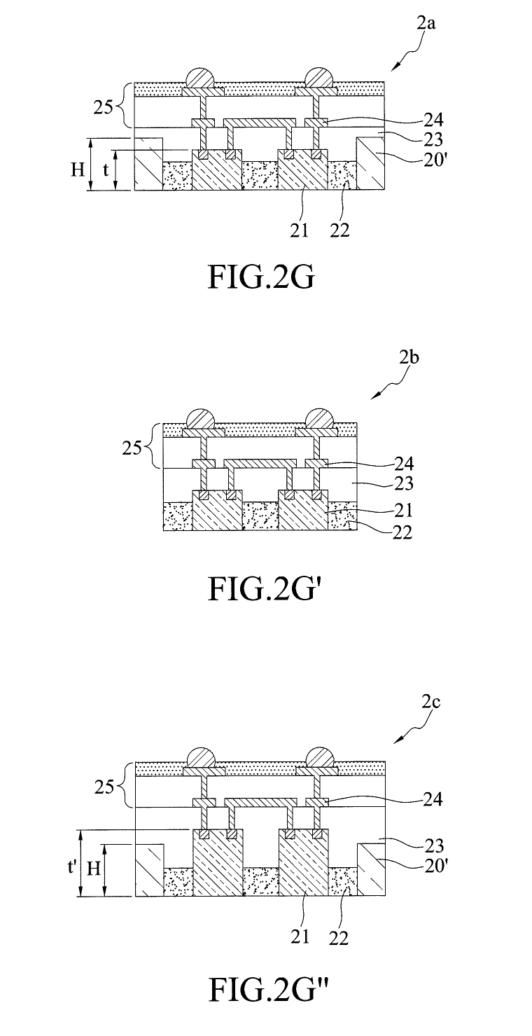

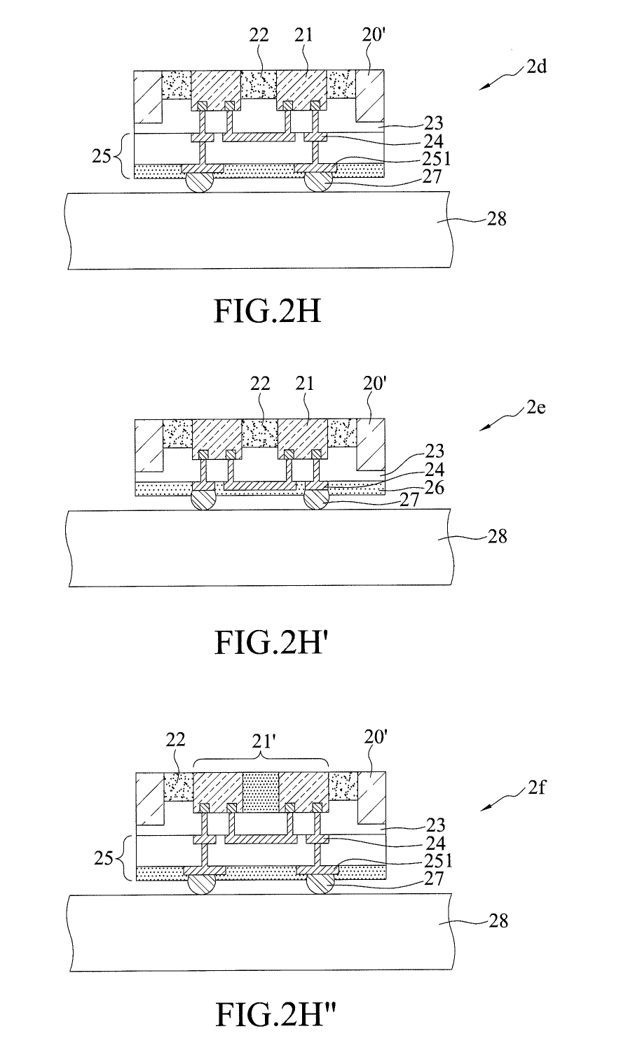

FIGS. 2A-2H are schematic cross-sectional views showing a method of fabricating a semiconductor package 2a-2f in accordance with a first embodiment of the present invention.

As shown in FIG. 2A, a carrier 20 having a plurality of grooves is provided.

In an embodiment, the carrier 20 is a silicon-containing board. The depth (d) of the groove 200 is a half of the thickness (T) of the carrier 20.

As shown in FIG. 2B, a plurality of semiconductor elements 21 are placed in the groove 200 of the carrier 20, and an adhesive material 22 is applied in the groove 200 and surrounds a periphery of the side surfaces 21c of the semiconductor element 21.

In an embodiment, the adhesive material 22 is epoxy resin. The semiconductor element 21 has opposing active surface 21a and non-active surface 21b and side surfaces 21a abutting the active surface 21a and the non-active surface 21b. A plurality of electrode pads 210 are formed on the active surface 21a. Through the on-active surface 21b, the semiconductor element 21 is adhered in the groove 200 via an adhesive layer 211, allowing the active surface 21a of the semiconductor element 21 to be positioned lower than the surface 20a of the carrier 20, without being protruded from the groove 200. The thickness (t) of the semiconductor element 21 is between 10 and 300 μm, preferably 20 to 150 μm. The thickness (m) of the bonding layer 211 is between 5 to 25 μm.

Moreover, the bonding layer 211 can be a die attach film (DAF), which can be formed on the non-active surface 21b of the semiconductor element 21. The semiconductor element 21 is placed in the groove 200. Alternatively, the bonding layer can be formed in the groove 200 (using a dispensing process shown in FIG. 2B″), followed by adhering the semiconductor element 21 in the groove via the adhesive layer 211.

In other embodiments, as shown in FIG. 2B′, the semiconductor element 21 protrudes from the groove 200, i.e., the active surface 21a of the semiconductor element 21 is positioned higher than the surface 20a of the carrier 20 to form a height difference (h).

Moreover, the semiconductor element is a single-chip structure, and two semiconductor elements 21 can be placed in a groove 200. However, the number of semiconductor elements placed in the groove 200 is not limited to two. In other embodiments, as shown in 2B″, the semiconductor element 21′ can be a multichip module. For example, two chips 212a and 212 b are bonded together with the bonding material 212 (epoxy resin) to form a module which is then placed in the groove.

As shown in FIG. 2C, following the process described in FIG. 2B, a dielectric layer 23 is formed on the carrier 20, the adhesive material 22, and the active surface 21a of the semiconductor element 21, with a plurality of blind vias 230 formed therein to expose the electrode pads 210 from the blind vias 230.

In an embodiment, the groove 200 is filled with the dielectric layer 23.

Moreover, the dielectric layer 23 is made of a non-organic material such as silicon oxide (SiO₂) or silicon nitride (SiₓN_{y}) or an organic material such as Polyimide (PI), Polybenzoxazole (PBO), or Benzocyciclobutene (BCB). The dielectric layer 23 and the adhesive material 22 are made of different materials.

In addition, blind vias 230 can be formed using chemical reactions (such as etching) or physical methods (such as laser).

As shown in FIG. 2D, a circuit layer 24 is formed on the dielectric layer 23, to form the conductive blind vias 240 in the blind vias 230, allowing the circuit layer 24 to be electrically connected with the electrode pads 210 of the active surface 21a of the semiconductor element 21 through the conductive vias 240.

In an embodiment, the circuit layer 24 is a wafer level circuit, rather than a packaging substrate level circuit. The minimal width and spacing of the circuits for packaging substrate is 12 μm. With the semiconductor process, it is possible to fabricate circuits below 3 μm in terms of width and spacing.

In the method of fabricating the semiconductor package according to the present invention, since the carrier 20 is made of a silicon-containing material, the heat expansion coefficient thereof is similar to that of the semiconductor element 21. Therefore, it is possible to prevent the occurrence of warpage of the carrier 20 leading to breakage of the semiconductor element 21, due to temperature cycle during the fabricating process, so as to prevent mismatch between the conductive vias 240 and the electrode pads 210.

As shown in FIG. 2E, a redistribution layer 25 is formed (RDL process) on the dielectric layer 23 and the circuit layer 24 and electrically connected with the circuit layer 24.

In an embodiment, the redistribution layer 24 comprises stacked dielectric portion 250 and circuit portion 251, and has an insulative protective layer 26 formed thereon. The insulative protective layer 26 has a plurality of openings 260, so as for the circuit member 251 to be exposed from the openings 260, in order for the conductive elements 27 to be bonded thereon.

Moreover, the dielectric layer 250 is made of a non-organic material such as silicon oxide (SiO₂) or silicon nitride (SiₓN_{y}) or an organic material such as Polyimide (PI), Polybenzoxazole (PBO), or Benzocyciclobutene (BCB).

As shown in FIG. 2F, a first portion of the carrier below the groove 200 of the carrier and the bonding layer 211 is removed to expose the non-active surface 21b of the semiconductor element and the adhesive material, so as to keep a second portion of the carrier 20 on a side wall of the groove 200 intact, for the second portion to function as a supporting member 20′.

As shown in FIG. 2G, a singulation process is performed following the singulation path S, to retain the supporting member 20′ to complete the fabricating process of one type of the semiconductor package 2a according to the present invention.

In an embodiment, the supporting member 20′ is a frame, and the thickness (t) of the semiconductor element 21 is not greater than the height (L) of the supporting member 20′.

Moreover, as shown in FIG. 2G′, during the singulation process, the supporting member 20′ is also removed to complete the fabricating process of one type of the semiconductor package 2b according to the present invention.

A subsequent process, as described in FIG. 2B′, is performed to obtain the semiconductor package 2c having a supporting member 20′, as shown in FIG. 2G″. The thickness t′ of the semiconductor element 21 is greater than the height (H) of the thickness (t′) of the semiconductor element 21,

In the method of fabricating a semiconductor package according to the present invention, the employment of the supporting member enhances the structured strength of the semiconductor package 2a, 2c.

As shown in FIG. 2H, following the fabricating process described in FIG. 2G, through the conductive elements 27, a substrate 28 is attached to the redistribution layer 25 and the circuit member of the redistribution layer 25 is electrically connected with the substrate 28, so as to complete the fabricating process of one type of the semiconductor package 2d according to the present invention.

As shown in FIG. 2H′, following the fabricating process described in FIG. 2D, after the circuit layer 24 is formed, an insulative protective layer 26 is formed on the circuit layer 24, with a plurality of openings 260 to expose the circuit layer 24. Accordingly, it allows the conductive elements 27 to be exposed from the circuit layer 24, followed by a singulation process, through the conductive elements 27. Then, the substrate is attached on the circuit layer 24 and the circuit layer 24 is electrically connected with the substrate 28. The fabricating process of one type of the semiconductor package 2e according to the present invention is then completed.

Following the process described in FIG. 2B, the fabricating process of the semiconductor package 2f having or not having (not shown) the supporting member 20′ is completed.

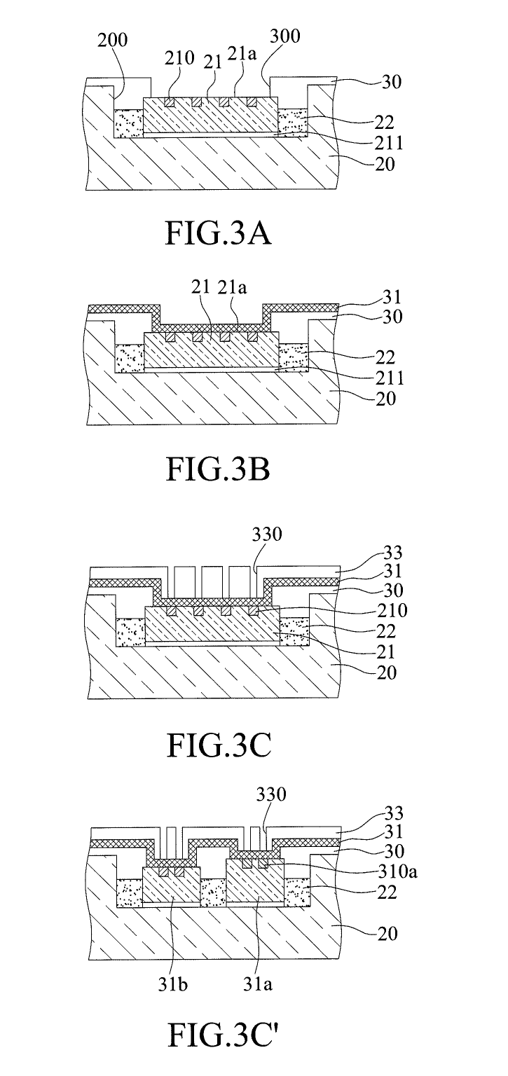

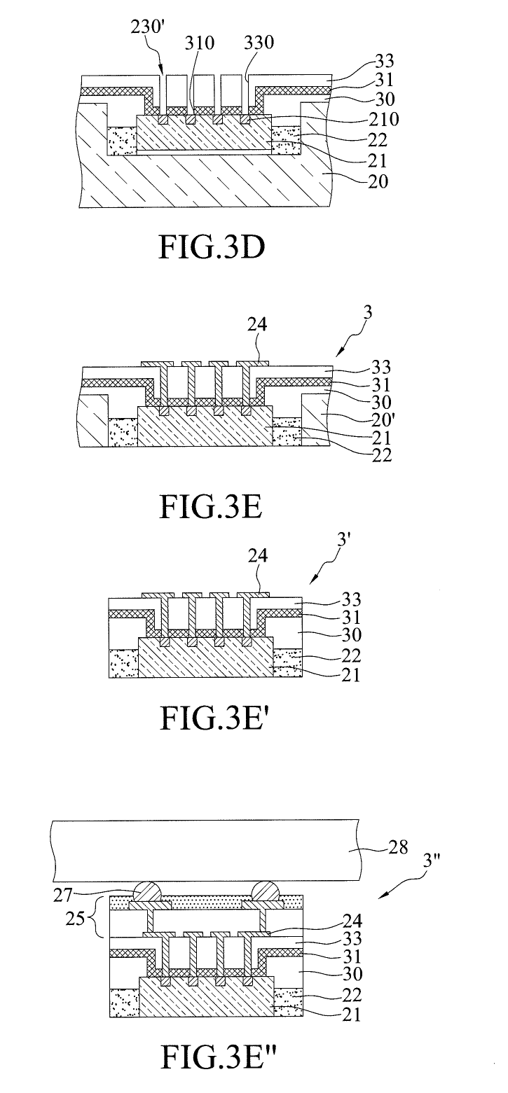

FIGS. 3A-3E are schematic cross-sectional views of a semiconductor package in accordance with a second embodiment of the present invention. The second embodiment differs from the first embodiment in the pre-procedure before the formation of the dielectric layer 33, while other processes are substantially the same, and therefore not repeated herein.

As shown in FIG. 3A, following the process descried in FIG. 2B (or following the process described in 2B′ or 2B″), a dielectric material 30 is formed on the carrier 20, the adhesive material 22, and the active surface 21a of the semiconductor element 21, for covering the periphery of the side surfaces of the semiconductor element 21. An opening 300 is formed through the dielectric material 30 so as to expose the active surface 21a of the semiconductor element 21 therefrom.

In an embodiment, the semiconductor element 21 can be but not limited to a single-chip structure, to be placed in a groove 200.

In addition, the dielectric layer 30 is made of a non-organic material such as silicon oxide (SiO₂) or silicon nitride (SiₓN_{y}) or an organic material such as Polyimide (PI), Polybenzoxazole (PBO), or Benzocyciclobutene (BCB).

The manner of forming the opening 300 is dependent on the characteristic of the dielectric material 30. If the dielectric material 30 has photosensitive property (such as organic material), the opening 300 can be directly formed through the dielectric material 30 using exposure and development method; if the dielectric material 30 does not has photosensitive property, the opening 300 can be formed by forming a patterned resist layer on the dielectric material 30 and then performing an etching process on the dielectric material 30.

As shown in FIG. 3B, an etch-stop layer is formed on the dielectric material 30 and the active surface 21a of the semiconductor element 21.

In an embodiment, the etch-stop layer 31 is made of silicon nitride (SiₓN_{y}).

As shown in FIG. 3C, the dielectric layer 33 is formed on the etch-stop layer 31, followed by performing an etching process to form a plurality of first through vias 330 in the dielectric layer 33.

In an embodiment, since an etching process is used to form the first through vias 330, the dielectric layer 23 and the etch-stop layer must be made of different materials. For example, the dielectric layer 23 can be made of silicon oxide (SiO₂).

As shown in FIG. 3D, a plurality of second through vias 310 are formed in the etch-stop layer 31, allowing the first through vias 330 to be connected with the second through vias 310 to form blind vias 230′. Accordingly, the electrode pads 210 of the semiconductor element 21 can be exposed from the blind vias 230′.

The use of the etch-stop layer 31 prevents damages of the semiconductor element 21 (such as electrode pads 210) from occurrence. It is because since the via height of the first through via 330 is deeper and it is hard to control the etching time over etching in the process of forming the first through vias 330 (or blind vias 230 in the first preferred embodiment) is easy to occur. Therefore, the provision of the etch-stop layer 31 is capable of protecting the semiconductor element 21 by forming the second through vias 310 with a shallower depth via the use of a slower etching solutions.

As shown in FIG. 3C′, another benefit of the provision of the etch-stop layer in another application is that, when a plurality of semiconductor elements 31a, 31b of different thickness are disposed in the groove 200, the electrode pads 310a of the thicker semiconductor element 331a can be protected from damages since the dielectric layer 33 on the thinner semiconductor element 31b requires longer etching time to form the first through vias 330.

As shown in FIGS. 3E, 3E′ and 3E″, a circuit layer 24 is subsequently formed (a redistribution layer 25 is formed, if desired, as shown in FIG. 3E′), followed by a singulation process (to form a supporting member 20′ as desired, as shown in FIG. 3E, or bonding with the substrate 28, as shown in FIG. 3E″), so as to complete the fabrication of the semiconductor package 3, 3′ and 3″.

Moreover, since there is no silicon interposer employed in the semiconductor package of the present invention, the overall thickness of the semiconductor package 2a-2f, 3, 3′, 3″ is much thinner.

In addition, in the semiconductor package 2a-2f, 3, 3′, 3″ according to the present invention, signals does not need to go though the conventional silicon interposer, much higher operational speed of the semiconductor element can be achieved.

A semiconductor package 2a-2f, 3, 3′, 3″ comprises: at least one semiconductor element 21, 21′, an adhesive material 22 formed on the periphery of the side surfaces 21c of the semiconductor element 21, 21′, a dielectric layer 23 formed on the adhesive material 22 and the active surface 21a of the semiconductor element 21, 21′, and a circuit layer 24 formed on the dielectric layer 23.

In an embodiment, the semiconductor element 21, 21′ is a multi-chip module or a single-chip structure, having an active surface 21a and an opposing non-active surface 21b, with a thickness t. t′ of 20 to 150 μm.

The dielectric layer 23 and the adhesive material 22 are made of different materials, and the dielectric layer 23 can be made of an organic material or a non-organic material.

The circuit layer 24 has a plurality of conductive vias 240 electrically connected with the semiconductor element 21, 21′.

In an embodiment, the semiconductor package 2a-2d, 2f, 3″ further comprises a redistribution layer 25 formed on the dielectric layer 23 and the circuit layer 24 and electrically connected with the circuit layer 24. The redistribution layer 25 comprises stacked dielectric portion 250 and circuit portion 251. The dielectric member 250 can be made of a non-organic material or an organic material.

In an embodiment, the semiconductor package 2d, 2f, 3″ may further comprise a substrate 28 mounted on the redistribution layer 25 and electrically connected with the redistribution layer 25.

In an embodiment, the semiconductor package 2e may further comprise a substrate 28 mounted on the circuit layer 24 and electrically connected with the circuit layer 24.

In an embodiment, the semiconductor package 2a, 2c-2f, 3 further comprises a supporting member 20′ surrounding the adhesive material 22. The supporting member 20′ is a silicon-containing frame. In an embodiment, the thickness (t) of the semiconductor element is not greater than the height (L) of the supporting member 20′. In another embodiment, the thickness t′ of the semiconductor element 21 is greater than the height (H) of the supporting member 20′.

In an embodiment, the semiconductor package 3, 3′, 3″ further comprises an etch-stop layer 31, such as silicon nitride, formed between the active surface 21a of the semiconductor element 21 and the dielectric layer 33. In an embodiment, the semiconductor package 3, 3′, 3″ further comprises a dielectric material 30, such as non-organic or organic material, formed on the adhesive material 22 and the active surface 21a of the semiconductor element 21 with an opening 300 to expose the active surface 21a of the semiconductor element 21. It thus allows the etch-stop layer 31 to be formed between the active surface 21a of the semiconductor element and the dielectric layer 33.

The forgoing non-organic material is silicon oxide (SiO₂) or silicon nitride (SiₓN_{y}) and the organic material is Polyimide (PI), Polybenzoxazole (PBO), or Benzocyciclobutene (BCB).

In summary, since there is no silicon interposer in the semiconductor package of the present invention, the overall thickness of the final product is much thinner when compared with the prior art. It thus allows the semiconductor element to have higher operational speed.

In addition, since the carrier is made of material containing silicon, the carrier is less likely to suffer from warpage.

Moreover, the supporting member is able to enhance the structured strength of the semiconductor package.

The present invention has been described using exemplary preferred embodiments. However, it is to be understood that the scope of the present invention is not limited to the disclosed embodiments. On the contrary, it is intended to cover various modifications and similar arrangements. The scope of the claims, therefore, should be accorded the broadest interpretation so as to encompass all such modifications and similar arrangements.

1-26. (canceled)

27: A method of fabricating a semiconductor package, comprising:
placing in a groove of a carrier a semiconductor element having opposing active and non-active surfaces and side surfaces abutting the active surface and the non-active surface;
applying an adhesive material in the groove and around a periphery of the side surfaces of the semiconductor element;
forming a dielectric layer on the adhesive material and the active surface of the semiconductor element;
forming on the dielectric layer a circuit layer electrically connected to the semiconductor element; and
removing a first portion of the carrier below the groove to keep a second portion of the carrier on a sidewall of the groove intact for the second portion to function as a supporting member.

28: The method of claim 27, wherein the carrier is a silicon-containing board.

29: The method of claim 27, wherein the carrier is formed with a plurality of the grooves, and a singulation process is performed after a first portion of the carrier below the grooves is removed.

30: The method of claim 29, wherein the supporting member is also removed during the singulation process.

31: The method of claim 27, wherein the groove has a depth less than a half of a thickness of the carrier.

32: The method of claim 27, wherein the semiconductor element is a multi-chip module or a single-chip package.

33: The method of claim 27, wherein the semiconductor element is between 10 to 300 μm in thickness.

34: The method of claim 27, wherein the semiconductor element is free from being protruded from the groove.

35: The method of claim 27, wherein the semiconductor element protrudes from the groove.

36: The method of claim 27, wherein the non-active surface of the semiconductor element is adhered in the groove via an adhesive layer.

37: The method of claim 36, wherein the adhesive layer is between 5 to 25 μm in thickness.

38: The method of claim 36, wherein the adhesive layer is also removed when the first portion of the carrier below the groove is removed.

39: The method of claim 27, wherein the dielectric layer is made of a non-organic material or an organic material.

40: The semiconductor package of claim 39, wherein the non-organic material is silicon oxide (SiO₂) or silicon nitride (SiₓN_{y}).

41: The semiconductor package of claim 39, wherein the organic material is Polyimide (PI), Polybenzoxazole (PBO), or Benzocyciclobutene (BCB).

42: The method of claim 27, wherein the dielectric layer and the adhesive material are made of different materials.

43: The method of claim 27, wherein the dielectric layer covers the periphery of the side surfaces of the semiconductor element.

44: The method of claim 27, wherein the groove is filled with the dielectric layer.

45: The method of claim 27, wherein the circuit layer is electrically connected to the semiconductor element via a plurality of conductive vias.

46: The method of claim 27, further comprising a redistribution layer formed on the dielectric layer and the circuit layer and electrically connected with the circuit layer.

47: The method of claim 46, wherein the redistribution layer comprises stacked dielectric portion and circuit portion.

48: The method of claim 47, wherein the dielectric portion is made of a non-organic material or an organic material.

49: The semiconductor package of claim 48, wherein the non-organic material is silicon oxide (SiO₂) or silicon nitride (SiₓN_{y}).

50: The semiconductor package of claim 48, wherein the organic material is Polyimide (PI), Polybenzoxazole (PBO), or Benzocyciclobutene (BCB).

51: The method of claim 46, further comprising, after the first portion of the carrier below the groove is removed, mounting and electrically connecting a substrate to the distribution layer.

52: The method of claim 27, further comprising, after the first portion of the carrier below the groove is removed, mounting and electrically connecting a substrate to the circuit layer.

53: The method of claim 27, further comprising, prior to forming the dielectric layer, forming an etch-stop layer on the active surface of the semiconductor element, allowing the dielectric layer to be formed on the etch-stop layer.

54: The method of claim 53, wherein the etch-stop layer is made of silicon nitride.

55: The method of claim 53, further comprising, prior to forming the etch-stop layer, forming on the adhesive material and the active surface of the semiconductor element a dielectric material covering the side surfaces of the semiconductor element, and forming an opening through the dielectric material for exposing the active surface of the semiconductor element, so as for the etch-stop layer to be formed on the active surface of the semiconductor element.

56: The method of claim 55, wherein the dielectric layer is made of a non-organic material or an organic material.

57: The method of claim 56, wherein the non-organic material is silicon oxide (SiO₂) or silicon nitride (SiₓN_{y}).

58: The method of claim 56, wherein the organic material is Polyimide (PI), Polybenzoxazole (PBO), or Benzocyciclobutene (BCB).
